(19) United States
(12) Patent Application Publication
(10) Pub. No.: US 2005/0009313 A1
(43) Pub. Date: Jan. 13, 2005

(54) Manufacturing method for semiconductor device

(75) Inventors: Nobuhiro Suzuki, Ichinomiya-Shi (JP); Kenji Imai, Anpachi-Gun (JP)

Correspondence Address: HOGAN & HARTSON L.L.P., 500 S. GRAND AVENUE, SUITE 1900, LOS ANGELES, CA, 90071-2611, US

(73) Assignee: SANYO ELECTRIC CO., LTD.

(21) Appl. No.: 10/861,337

(22) Filed: Jun. 4, 2004

(30) Foreign Application Priority Data
Jun. 6, 2003 (JP) 2003-162408

(51) Int. Cl. H01L 21/44; H01L 21/301; H01L 21/46; H01L 21/78

(52) U.S. Cl. 438/611; 438/597; 438/461; 438/460; 438/464

(57) ABSTRACT

An internal wire is formed via an oxide film on the front surface of a semiconductor substrate so as to extend toward the boundary relative to an adjacent integrated circuit region. An upper supporting base is fixedly formed on the front surface of the semiconductor substrate by means of a resin layer of epoxy adhesive or the like, and a lower supporting base is fixedly formed on the back surface of the semiconductor substrate by means of a resin layer of epoxy adhesive or the like, whereby a laminated body is formed. The resin layer and the internal wire are partially removed, leaving a portion of the laminated body, to thereby form an inverted-V shaped groove (a cut-off groove) where a part of the internal wire is exposed to the outside. Thereafter, the resulting cut-off groove is exposed to plasma atmosphere to thereby dissolve, and thus remove, any remaining resin fragments attached to the exposed end portion of the internal wire.

### CROSS-REFERENCE TO RELATED APPLICATIONS

The priority application Number No.2003-162408 upon which this patent application is based is hereby incorporated by reference.

### FIELD OF THE INVENTION

The present invention relates to a method for manufacturing a semiconductor device which contains a laminated internal wire and resin layers.

### DESCRIPTION OF THE RELATED ART

In recent years, chip size packages (CSP) have come to be widely used in order to reduce the size of chips for semiconductor devices.

FIGS. 11A and 11B show external appearance of upper and lower surfaces of a semiconductor device utilizing a chip size package. A semiconductor integrated device utilizing a chip size package is generally constructed such that a semiconductor chip 10 is sandwiched via resin layers 12 of epoxy or the like between an upper supporting base 14 and a lower supporting base 16, with an outside wire 30 extending from the lateral side of the resultant body to be connected to a ball terminal 20 formed on the back surface of the element.

Such a semiconductor device utilizing a chip size package is manufactured using a method basically comprising the steps shown in FIGS. 1 to 8: formation of an integrated circuit element and an internal wire (S10), formation of a first laminated body (S12), grinding (S14), formation of a second laminated body (S16), cutting (S18), formation of a metal film (S20), formation of a terminal (S22), and dicing (S24).

At the cutting stage (S18), an inverted-V shaped groove (a cut-off groove) 2 is formed on a lower supporting base 16, using a dicing saw or the like, so as to be deep enough to reach the opposed upper supporting base 14, whereby the end portion 28 of the internal wire 26 of the semiconductor chip 10 is exposed to the outside.

However, in a semiconductor device utilizing a chip size package manufactured using the above-described conventional technique, portions of resin (resin fragments 13) tend to attach to the exposed end portion 28 of the internal wire 26 of the semiconductor chip 10, as shown in the enlarged view FIG. 6 of a semiconductor device after the cutting step.

Consequently, the contact resistance between the end portion 28 of the internal wire 26 and an outside wire 30 to be formed in a subsequent stage disadvantageously increases, while the reliability of the device drops.

### SUMMARY OF THE INVENTION

According to the present invention, there is provided a method for manufacturing a semiconductor device, comprising a first step of fixedly forming a supporting base on a semiconductor substrate having an internal wire formed thereon, via a resin layer, whereby a laminated body is formed on the semiconductor substrate; a second step of removing at least a part of the resin layer and a part of the internal wire, while leaving a part of the laminated body, to thereby form a groove where a part of the internal wire is exposed to outside; a third step of exposing the groove formed in the laminated body to plasma atmosphere for cleaning; a fourth step of forming a metal film covering a surface of the laminated body and the groove; and a fifth step of patterning the metal film into an outside wire, wherein the plasma atmosphere is plasma atmosphere capable of etching the resin layer.

### BRIEF DESCRIPTION OF THE DRAWINGS

FIG. 1 is a diagram showing formation of an integrated circuit element and an internal wire according to an embodiment of the present invention;

FIG. 2 is a diagram showing formation of a first laminated body in the embodiment of the present invention;

FIG. 3 is a diagram showing grinding in the embodiment of the present invention;

FIG. 4 is a diagram showing formation of a second laminated body in the embodiment of the present invention;

FIG. 5 is a diagram showing cutting in the embodiment of the present invention;

FIG. 6 is an enlarged view showing a semiconductor device subjected to cutting in the embodiment of the present invention;

FIG. 7 is a diagram showing formation of a metal film in embodiment of the present invention;

FIG. 8 is a diagram showing formation of a terminal in the embodiment of the present invention;

FIG. 9 is a diagram showing dicing in the embodiment of the present invention;

FIG. 10 is a diagram showing a manufacturing process according to another embodiment of the present invention;

FIG. 11A is a diagram showing an external appearance of an upper surface of a semiconductor device utilizing a chip size package; and

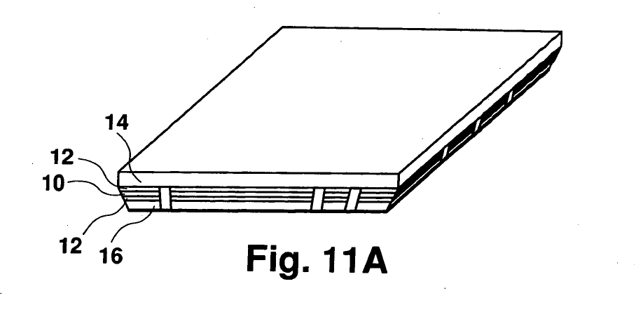

FIG. 11B is a diagram showing an external appearance of a lower surface of a semiconductor device utilizing a chip size package.

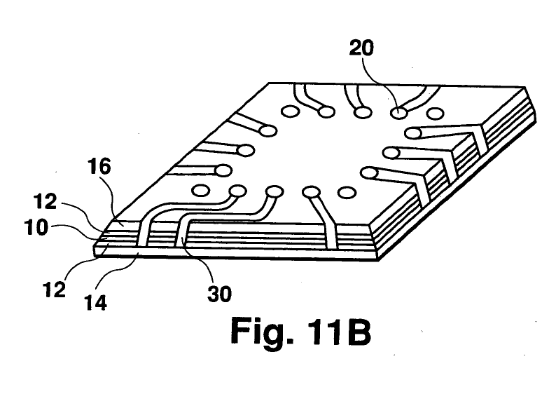

### DESCRIPTION OF THE PREFERRED EMBODIMENTS

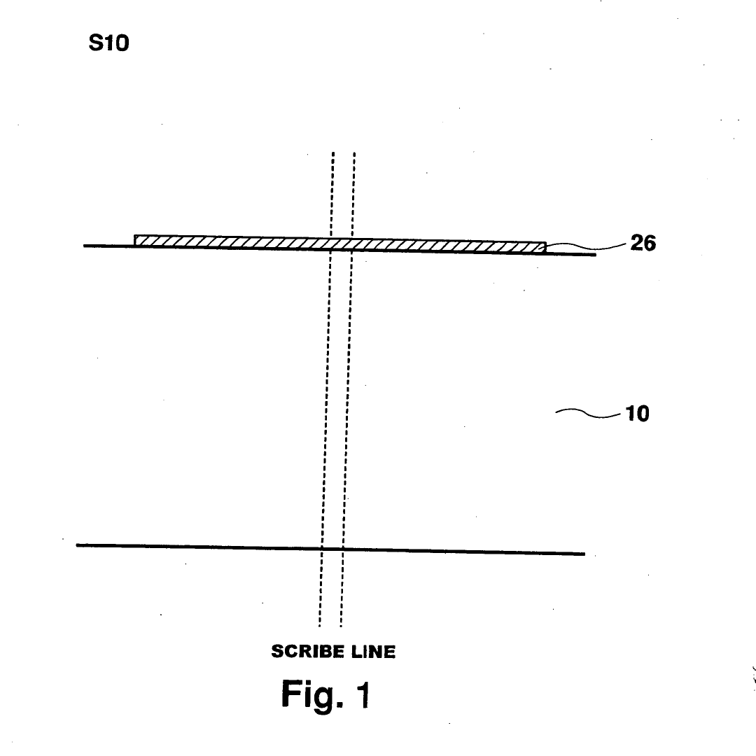

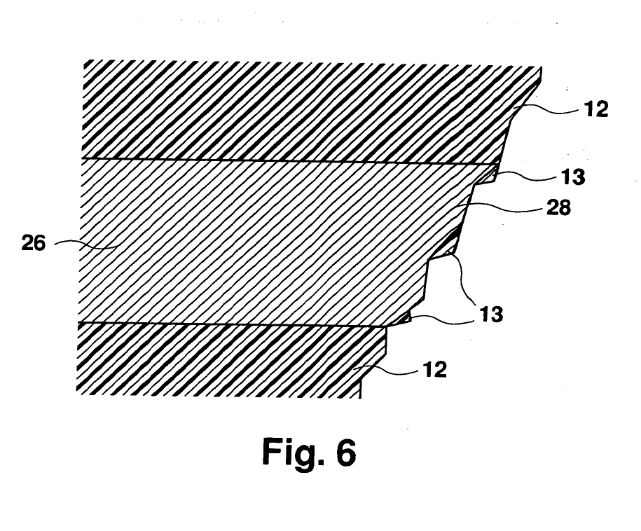

A method for manufacturing a semiconductor device according to an embodiment of the present invention comprises, as illustrated in FIGS. 1 to 8, formation of an integrated circuit element and an internal wire (S10), formation of a first laminated body (S12), grinding (S14), formation of a second laminated body (S16), cutting (S18), formation of a metal film (S20), formation of a terminal (S22), and dicing (S24).

At the step S10 for formation of an integrated circuit element and an internal wire, as shown in FIG. 1, an integrated circuit is formed in each region defined by a scribe line on the front surface of a semiconductor chip 10. Thereafter, an internal wire 26 is formed, via an oxide film, so as to extend toward the boundary relative to an adjacent integrated circuit element. The internal wire 26 is electrically connected to the associated integrated circuit element via a contact hole formed throughout the oxide film.

The semiconductor substrate 10 can be made using typical semiconductor material, such as silicon, gallium arsenide, or the like. An integrated circuit for a light receiving element, such as a CCD, can be formed using any applicable known semiconductor processing technique. The internal wire 26 can be formed using mainly a material that is generally usable for a semiconductor device, such as silver, gold, copper, aluminum, nickel, titan, tantalum, and tungsten, with aluminum often being preferable in consideration of electrical resistance value and material processability.

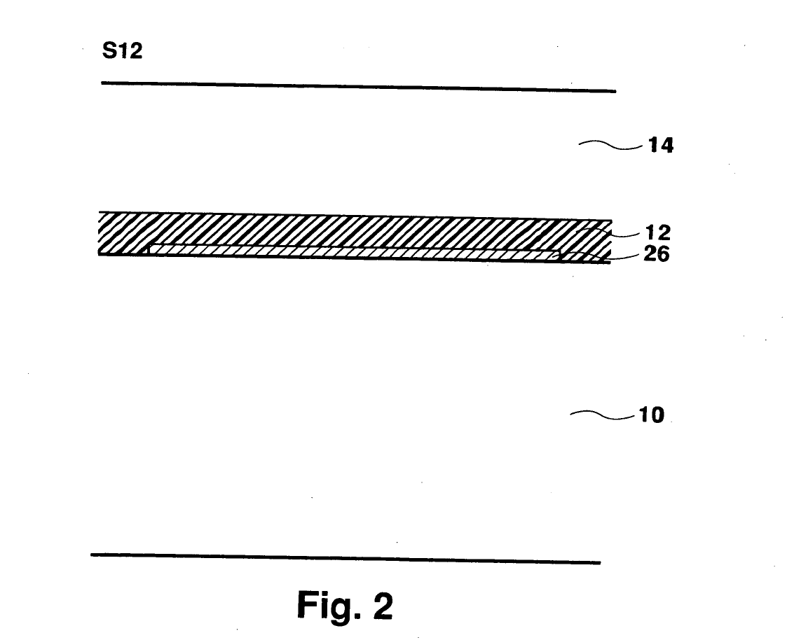

At the step S12 for formation of a first integrated body, as shown in FIG. 2, an upper supporting base 14 is fixedly formed, via a resin layer 12 of epoxy adhesive, or the like, on the front surface of the semiconductor chip 10 where the integrated circuit element is formed.

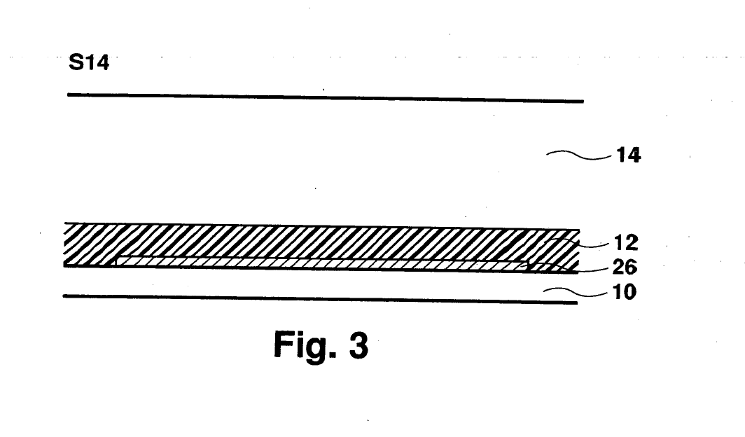

At the step S14 for grinding, as shown in FIG. 3, the back surface of the semiconductor chip 10 is mechanically ground using a grinder or the like to thereby reduce the thickness of the semiconductor chip 10.

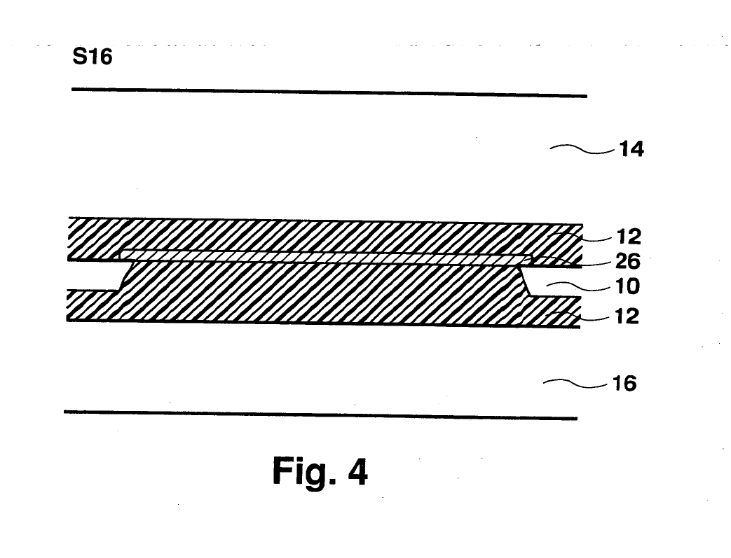

At the step S16 for formation of a second integrated body, as shown in FIG. 4, the back surface of the semiconductor chip 10 is etched along the scribe line such that the surface of the oxide film where the internal wire 26 is formed is exposed to the outside. Then, a lower supporting base 16 is fixedly formed on the back surface of the semiconductor substrate 10 by means of a resin layer 12 of epoxy adhesive or the like, whereby a laminated body is formed on the back surface of the semiconductor substrate 10.

The upper supporting base 14 and the lower supporting base 16 can be formed using a material desirably selected from those which are useable for packaging of a semiconductor device, including, glass, plastic, metal, ceramic, or the like. For example, in the case where a light receiving element, such as a CCD, is formed on a semiconductor substrate, transparent glass or plastic is preferably used to form the upper supporting base 14.

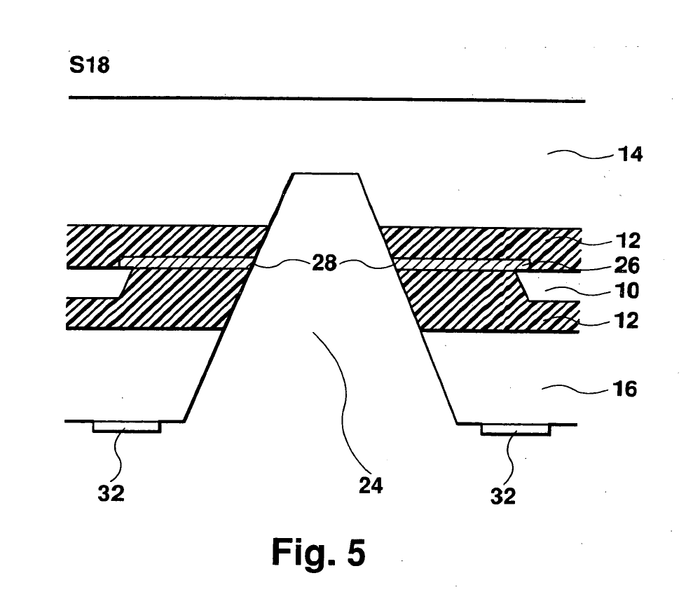

At the step S18 for cutting, as shown in FIG. 5, a buffer member 32 is formed on the back surface of the lower supporting base 16 at a position where a ball terminal 20 is to be formed in a subsequent step. The buffer member 32 will serve as a cushion for buffering stress applied to the ball terminal 20. The buffer member 32 maybe formed using flexible material adapted to patterning, with a light sensitive epoxy resin being preferably used.

Thereafter, an inverted-V shaped groove (a cut-off groove) 24 is formed on the lower supporting base 16, using a dicing saw or the like, so as to be deep enough to reach the opposed upper supporting base 14. As a result, the end portion 28 of the internal wire 26 is exposed to the outside along the inside surface of the cut-off groove 24. At this stage, resin fragment 13 cut off from the resin layer 12 tend to attach to the exposed end portion 28 of the internal wire 26. The attached resin fragments 13 are pieces of resin which melted from the resin layer 12 and attached to the end portion 28 of the internal wire during application of a dicing saw or the like, which is rotating at a high speed, to the resin layer 12 in order to form the cut-off groove. After curing, these resin fragments are not soluble in organic solvent such as isopropyl alcohol, and thus cannot be sufficiently removed through ultrasonics cleaning using organic solvent.

When the manufacturing process proceeds to a subsequent step with the resin fragments 13 remaining attached to the end portion 28 of the internal wire 26, contact resistance between the metal film 30 and the exposed end portion 28 of the internal wire 26 will increase and the reliability of the device will decrease.

In order to address this problem, after formation of the cut-off groove 24, the resultant cut-off groove 24 is exposed to plasma atmosphere which is capable of etching the resin layer 12 and the resin fragments 13 to thereby dissolve, and thus remove, the resin fragments 13 attached on the end portion 28. It should be noted that 02 plasma or CF₄ plasma may be preferably used as the above-described plasma atmosphere.

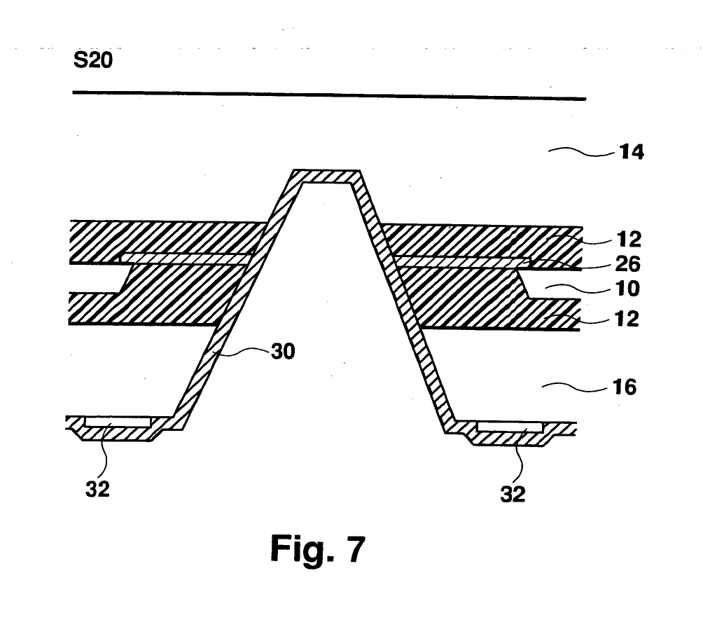

At step S20 for formation of a metal film, as shown in FIG. 7, a metal film 30 is formed on the lower supporting base 16 where the cut-off groove 24 is formed. As covering the internal surface and lateral surfaces of the cut-off groove 24, the metal film 30 is electrically connected to the internal wire 26. Thereafter, the metal film 30 is patterned into a predetermined wire pattern.

The metal film 30 is formed using mainly a material that is generally used in a semiconductor device, such as, for example, silver, gold, copper, aluminum, nickel, titan, tantalum, tungsten, or the like, with aluminum often being preferable in terms of electric resistance value and material processability.

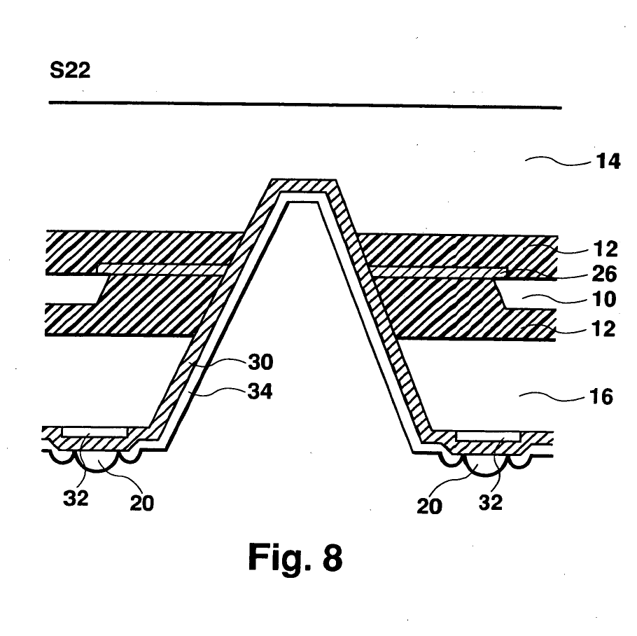

At step S22 for formation of a terminal, as shown in FIG. 8, a protective film 34 is formed so as to cover the back surface of the lower supporting base 16 except an area corresponding to the buffer member 32. The protective film 34 is formed using a material adapted to patterning, with light sensitive epoxy resin or the like being preferably used, similar to the buffer member 32. A ball terminal 20 is thereafter formed as an outside terminal on the buffer member 32 on the lower supporting base 16, from, for example, a solder material formed using a conventional method.

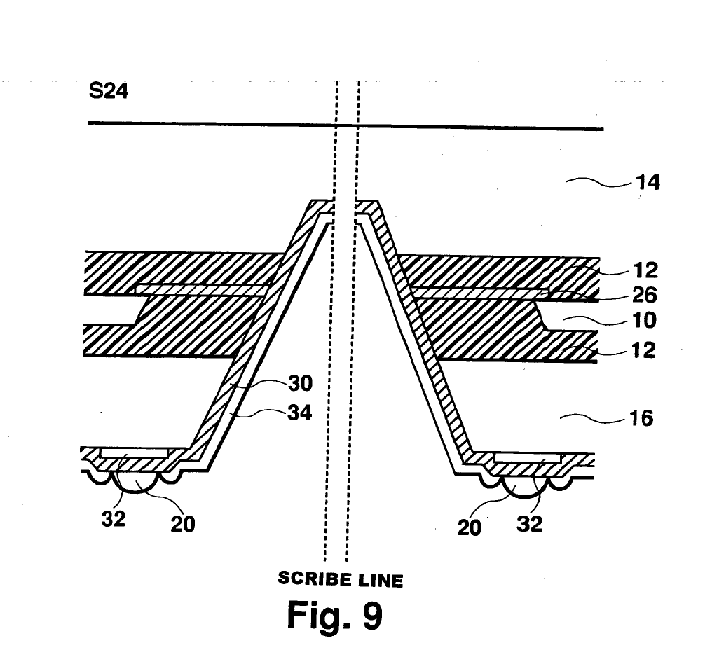

At step S24 for dicing, as shown in FIG. 9, the resultant laminated body is cut into individual semiconductor devices along a scribe line assumed along the bottom portion of the cut-off groove 24, using a dicing saw, or the like.

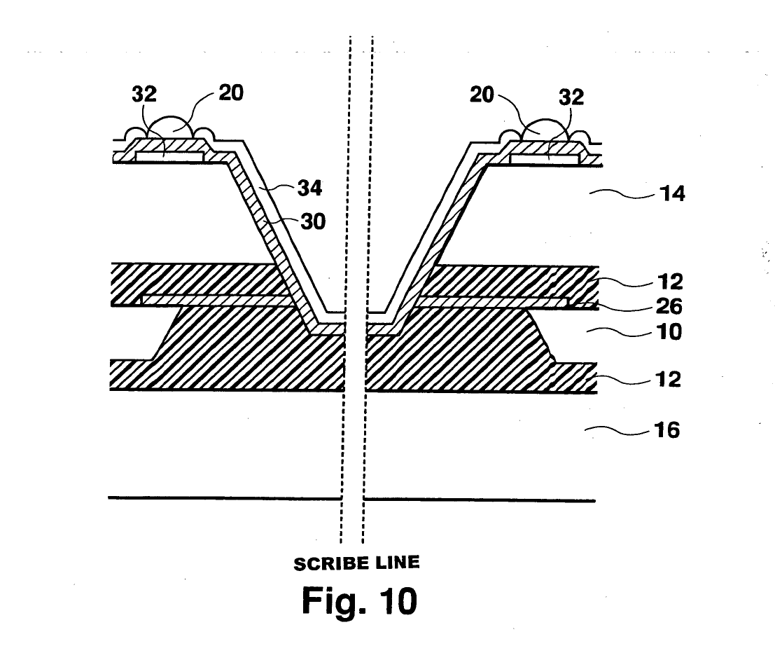

FIG. 10 shows another example of a semiconductor device 10 according to the present invention. The illustrated semiconductor device is manufactured using the method outlined below.

In this method, an integrated circuit element and an internal wire are initially formed, and an upper supporting base 14 is then fixedly formed on the front surface of the semiconductor chip 10 by means of a resin layer 12 of epoxy adhesive or the like. Thereafter, a buffer member 32 is formed on the front surface of the upper supporting base 14 at a point where a ball terminal 20 is to be formed in a subsequent step.

Then, a V-shaped groove (a cut-off groove) 24 is formed on the upper supporting base 14, using a dicing saw or the like, so as to form a groove deep enough to reach to the semiconductor substrate 10. As a result, the end portion 28 of the internal wire 26 is exposed to the outside along the inside surface of the cut-off groove 24. The cut-off groove 24 is then exposed in plasma atmosphere to thereby dissolve, and thus remove, cut-off resin fragments 13 attached to the end portion 28 of the internal wire. Further, a metal film 30 is formed on the upper supporting base 14 where the cut-off groove 24 is formed. As covering the bottom and lateral surfaces of the cut-off groove 24, the metal film 30 is electrically connected to the internal wire 26. Thereafter, the metal film 30 is patterned into a predetermined wire pattern.

Further, a protective film 34 is formed over the upper supporting base 14, except in an area corresponding to the buffer member 32, and a ball terminal 20 is then formed as an outside terminal on the buffer member 32 of the upper supporting base 14. The back surface of the semiconductor chip 10 is mechanically ground using a grinder to thereby reduce the thickness of the semiconductor chip 10. Then, the back surface of the semiconductor chip 10 is etched along the scribe line such that the surface of the oxide film where the internal wire 26 is laminated is exposed to the outside. Further, a lower supporting base 16 is fixedly formed on the back surface of the semiconductor substrate 10 by means of a resin layer of epoxy resin, or the like, to thereby form a laminated body on the back surface of the semiconductor substrate 10.

Finally, the laminated body is cut into individual semiconductor devices along the scribe line assumed along the bottom portion of the cut-off groove 24, using a dicing saw or the like.

1. A method for manufacturing a semiconductor device, comprising:
a first step of fixedly forming a supporting base on a semiconductor substrate having an internal wire formed thereon, via a resin layer, whereby a laminated body is formed on the semiconductor substrate;
a second step of removing at least a part of the resin layer and a part of the internal wire, while leaving a part of the laminated body, to thereby form a groove where a part of the internal wire is exposed to the outside;
a third step of exposing the groove formed in the laminated body to plasma atmosphere for cleaning;
a fourth step of forming a metal film covering a surface of the laminated body and the groove; and
a fifth step of patterning the metal film into an outside wire,
wherein
the plasma atmosphere is plasma atmosphere capable of etching the resin layer.

2. A method for manufacturing a semiconductor device, comprising:
a first step of forming an integrated circuit in each region defined by a scribe line on a front surface of a semiconductor substrate and forming an internal wire extending toward a boundary relative to an adjacent integrated circuit region;
a second step of fixedly forming an upper supporting base on the front surface of the semiconductor substrate via a first insulating resin layer so as to cover an area where the integrated circuit is formed;
a third step of removing the semiconductor substrate along the scribe line and fixedly forming a lower supporting base on a back surface of the semiconductor substrate via a second insulating resin layer, whereby a laminated body is formed on the back surface of the semiconductor substrate;
a fourth step of forming a groove along the scribe line, where a part of the second insulating resin and a part of the internal wire are exposed to the outside, while leaving a part of the upper supporting base;
a fifth step of exposing the groove formed in the laminated body to plasma atmosphere for cleaning;
a sixth step of forming a metal film covering the back surface of the semiconductor substrate and the groove;
a seventh step of patterning the metal film into an outside wire; and
an eighth step of cutting the upper supporting base to thereby divide the laminated body into individual semiconductor devices,
wherein
the plasma atmosphere is plasma atmosphere capable of etching resin forming the second insulating resin layer.

3. A method for manufacturing a semiconductor device, comprising:
a first step of forming an integrated circuit in each region defined by a scribe line on a front surface of a semiconductor substrate and forming an internal wire extending toward a boundary relative to an adjacent integrated circuit region;
a second step of fixedly forming an upper supporting base on the front surface of the semiconductor substrate via a first insulating resin layer so as to cover an area where the integrated circuit is formed;
a third step of forming a groove along the scribe line, where a part of the first insulating resin layer and a part of the internal wire are exposed to outside, while leaving a part of the semiconductor substrate;
a fourth step of exposing the groove to plasma atmosphere for cleaning;
a fifth step of forming a metal film covering the front surface of the semiconductor substrate and the groove;
a sixth step of patterning the metal film into an outside wire;
a seventh step of removing the semiconductor substrate along the scribe line and fixedly forming a lower supporting base on a back surface of the semiconductor substrate via a second insulating resin layer, whereby a laminated body is formed on the back surface of the semiconductor substrate; and
an eighth step of cutting the lower supporting base to thereby divide the laminated body into individual semiconductor devices, wherein
the plasma atmosphere is a plasma atmosphere capable of etching resin forming the first insulating resin layer.

4. The method for manufacturing a semiconductor device according to claim 2, wherein
the integrated circuit formed on the front surface of the semiconductor device is a light receiving element, and the upper supporting base is a transparent supporting base.

5. The method for manufacturing a semiconductor device according to claim 1, wherein
the plasma atmosphere comprises O₂ plasma or CF₄ plasma.

6. The method for manufacturing a semiconductor device according to claim 2, wherein
the plasma atmosphere comprises O₂ plasma or CF₄ plasma.

7. The method for manufacturing a semiconductor device according to claim 3, wherein
the plasma atmosphere comprises O₂ plasma or CF₄ plasma.

8. The method for manufacturing a semiconductor device according to claim 4, wherein
the plasma atmosphere comprises O₂ plasma or CF₄ plasma.
